(19) United States
(12) Patent Application Publication
(10) Pub. No.: US 2024/0109771 A1
(43) Pub. Date: Apr. 4, 2024

(54) METHODS FOR SEALING CAVITIES IN MICRO-FABRICATED DEVICES AND MICRO-FABRICATED DEVICES FABRICATED IN ACCORDANCE WITH SAME

(71) Applicant: The University of British Columbia, Vancouver (CA)

(72) Inventors: Kenichi TAKAHATA, Vancouver (CA); Nabil SHALABI, Boston, MA (US); Kyle Albert SEARLES, Austin, TX (US)

(21) Appl. No.: 18/476,229

(22) Filed: Sep. 27, 2023

Related U.S. Application Data
(60) Provisional application No. 63/410,287, filed on Sep. 27, 2022.

(51) Int. Cl. B81C 1/00; B81B 3/00

(52) U.S. Cl. CPC B81C 1/00293; B81B 3/0021; B81B 2203/0127; B81C 2203/0172

(57) ABSTRACT

A method for fabricating a micro-fabricated device comprising a cavity-defining surface which defines a cavity, comprises: fabricating a channel that provides fluid communication with the cavity, the channel comprising a Tesla valve for permitting fluid flow in a first direction out of the cavity and through the channel while impeding fluid flow through the channel into the cavity in a second direction opposed to the first direction; and applying a sealing material to the device to thereby seal the channel, wherein applying the sealing material comprises: introducing the sealing material to the channel; and depositing the sealing material onto one or more channel-defining surfaces. The sealing material is prevented from reaching the cavity at least in part by the action of the Tesla valve.

### CROSS-REFERENCE TO RELATED APPLICATIONS

This application claims the benefit under 35 U.S.C. § 119 of application No. 63/410287, filed 27 Sep. 2023, and entitled SWITCH MODE CAPACITIVE PRESSURE SENSORS which is hereby incorporated herein by reference for all purposes.

### FIELD

The technology described herein applies to micro-fabricated devices and methods for fabricating same. Particular non-limiting embodiments employ microlithographic fabrication techniques. Particular non-limiting embodiments provide microelectromechanical (MEMs) devices and methods for fabricating same.

### BACKGROUND

A variety of micro-fabricated devices are fabricated to define cavities or voids which can provide a variety of uses to such micro-fabricated devices. For example, MEMs devices can be fabricated to define cavities into which the device can move or deform. In accordance with some micro-fabrication techniques, cavities are fabricated by: depositing a so-called sacrificial layer onto a substrate; coating the sacrificial layer with one or more other device layers while leaving one or more channels which provides access to the sacrificial layer; and then etching away the sacrificial layer with etchant (a typically acidic liquid) which is brought into contact with the sacrificial layer through the channel(s) where the etchant dissolves the sacrificial layer and carries the material of the sacrificial layer (in solution) out of the device via the channels to leave behind a cavity or void in place of the sacrificial layer.

In some applications, there is a desire to seal the channel(s) after the fabrication of a micro-fabricated cavity. Sealing the channel(s) after fabrication of a micro-fabricated cavity may prevent fluids or other contaminants from entering or egressing from the cavity. As a non-limiting example, in some applications and/or devices, it might be desirable to evacuate the cavity, in which case, there is a desire to seal any channel(s) used to fabricate the cavity to maintain the vacuum. Sealing such channel(s) may involve coating the exposed surfaces (e.g. the channel-defining surface(s) of the channel-defining wall(s)) with a coating material that solidifies or is caused to solidify on the channel-defining surface(s) to fill the channel(s), thereby sealing the channel(s).

A drawback with prior art sealing techniques is that some of the sealant material can travel through the channel(s) and into the cavity, where such material ends up inside the cavity after sealing. This contamination of the cavity with sealing material can be undesirable in particular applications.

There is a general desire to provide improved methods for sealing cavities in micro-fabricated devices and to fabricate devices which take advantages of these techniques. There is a general desire to provide improved micro-fabricated devices. There is a general desire to provide methods for sealing cavities in micro-fabricated devices which at least ameliorate the drawbacks with prior art techniques.

### SUMMARY

One aspect of the invention provides a method for fabricating a micro-fabricated device comprising a cavity-defining surface which defines a cavity. The method comprises: fabricating a channel that provides fluid communication with the cavity, the channel comprising a Tesla valve for permitting fluid flow in a first direction out of the cavity and through the channel while impeding fluid flow through channel into the cavity in a second direction opposed to the first direction; and applying a sealing material to the device to thereby seal the channel, wherein applying the sealing material comprises: introducing the sealing material to the channel; and depositing the sealing material onto one or more channel-defining surfaces. The sealing material is prevented from reaching the cavity at least in part by the action of the Tesla valve.

Applying the sealing material to the device may be performed in a vacuum environment to thereby vacuum seal the cavity by sealing the channel.

Applying the sealing material may comprise applying the sealing material using a conformal coating process. Applying the sealing material may comprise applying the sealing material using a vapor deposition process. Applying the sealing material may comprise applying the sealing material using a conformal vapor deposition process.

Fabricating the channel may comprise: shaping the channel to provide one or more dead-end paths; shaping the channel to provide one or more circuitous path shapes; and/or shaping the channel to provide one or more serpentine (S-shaped) channel shapes.

The method may comprise fabricating the cavity. Fabricating the cavity may comprise: depositing a sacrificial layer on a substrate; depositing a covering layer over the sacrificial layer; and after depositing the covering layer: etching the sacrificial layer; and extracting the etched sacrificial layer through the channel in the first direction to leave the cavity in the volume occupied by the sacrificial layer prior to etching.

The cavity-defining surface may comprise a plurality of electrically conductive surface elements.

The plurality of electrically conductive surface elements may comprise a membrane electrode provided by a membrane element. The membrane electrode may be deformable into the cavity.

The plurality of electrically conductive surface elements may comprise one or more static switch electrodes provided by one or more corresponding switch elements. The one or more static switch electrodes may be located on a portion of the cavity-defining surface generally opposed to the membrane electrode. The membrane electrode may be deformable across the cavity to make electrical contact between the membrane electrode and the one or more switch electrodes.

The one or more static switch electrodes may comprise a plurality of static switch electrodes. The method may comprise locating the plurality of static switch electrodes in such a manner that an amount of deformation of the membrane electrode is positively correlated with a number of the plurality of switch electrodes with which the membrane electrode makes electrical contact.

Electrical contact between the membrane and a particular one of the one or more switch electrodes may complete a corresponding particular circuit. The corresponding particular circuit may comprise a corresponding particular circuit element.

The particular circuit element may comprise a discrete capacitive element. The particular circuit element may comprise at least one of: one or more capacitive elements, one or more inductive elements, one or more resistive elements, one or more solid state transistors, one or more solid state diodes, one or more resonating circuit elements, one or more power sources and one or more electrically activated switches.

The particular circuits completed by the electrical contact between the membrane and the particular ones of the plurality of switch electrodes may be connected in parallel with one another.

The membrane may be deformable under an influence of at least one of: external pressure and heat. An amount of deformation of the membrane may be positively correlated with an amount of the external pressure or heat.

The method may comprise fabricating a static touch-mode electrode on a side of the cavity generally opposite the membrane electrode. A touch-mode capacitance provided by the membrane electrode and the touch-mode electrode may be positively correlated with the amount of deformation of the membrane electrode. The touch-mode electrode may be coated with a dielectric layer, the dielectric layer providing a portion of the cavity-defining surface. The touch mode capacitance may be connected in parallel with the particular circuits completed by the electrical contact between the membrane and the particular ones of the plurality of switch electrodes.

Another aspect of the invention provides use of a Tesla valve in fabricating a micro-fabricated device comprising a cavity-defining surface which defines a cavity. The us comprises: fabricating a channel that provides fluid communication with the cavity, the channel comprising a Tesla valve for permitting fluid flow in a first direction out of the cavity and through the channel while impeding fluid flow through channel into the cavity in a second direction opposed to the first direction; fabricating the cavity, wherein fabricating the cavity comprises: depositing a sacrificial layer on a substrate; depositing a covering layer over the sacrificial layer; and, after depositing the covering layer: etching the sacrificial layer; and extracting the etched sacrificial layer through the channel in the first direction to leave the cavity in the volume occupied by the sacrificial layer prior to etching. The use comprises, after extracting the etched sacrificial layer through the channel, applying a sealing material to the device to thereby seal the channel, wherein applying the sealing material comprises: introducing the sealing material to the channel; and depositing the sealing material onto one or more channel-defining surfaces. The sealing material is prevented from reaching the cavity at least in part by the action of the Tesla valve.

Applying the sealing material to the device may be performed in a vacuum environment to thereby vacuum seal the cavity by sealing the channel.

Applying the sealing material may comprise applying the sealing material using a conformal coating process. Applying the sealing material m ay comprise applying the sealing material using a vapor deposition process. Applying the sealing material may comprise applying the sealing material using a conformal vapor deposition process.

Fabricating the channel may comprise: shaping the channel to provide one or more dead-end paths; shaping the channel to provide one or more circuitous path shapes; and/or shaping the channel to provide one or more serpentine (S-shaped) channel shapes.

The cavity-defining surface may comprise a plurality of electrically conductive surface elements.

The plurality of electrically conductive surface elements may comprise a membrane electrode provided by a membrane element. The membrane electrode may be deformable into the cavity.

The plurality of electrically conductive surface elements may comprise one or more static switch electrodes provided by one or more corresponding switch elements. The one or more static switch electrodes may be located on a portion of the cavity-defining surface generally opposed to the membrane electrode. The membrane electrode may be deformable across the cavity to make electrical contact between the membrane electrode and the one or more switch electrodes.

The one or more static switch electrodes may comprise a plurality of static switch electrodes. The use may comprise locating the plurality of static switch electrodes in such a manner that an amount of deformation of the membrane electrode is positively correlated with a number of the plurality of switch electrodes with which the membrane electrode makes electrical contact.

Electrical contact between the membrane and a particular one of the one or more switch electrodes may complete a corresponding particular circuit. The corresponding particular circuit may comprise a corresponding particular circuit element.

The particular circuit element may comprise a discrete capacitive element. The particular circuit element may comprise at least one of: one or more capacitive elements, one or more inductive elements, one or more resistive elements, one or more solid state transistors, one or more solid state diodes, one or more resonating circuit elements, one or more power sources and one or more electrically activated switches.

The particular circuits completed by the electrical contact between the membrane and the particular ones of the plurality of switch electrodes may be connected in parallel with one another.

The membrane may be deformable under an influence of at least one of: external pressure and heat. An amount of deformation of the membrane may be positively correlated with an amount of the external pressure or heat.

The use may comprise fabricating a static touch-mode electrode on a side of the cavity generally opposite the membrane electrode. A touch-mode capacitance provided by the membrane electrode and the touch-mode electrode may be positively correlated with the amount of deformation of the membrane electrode. The touch-mode electrode may be coated with a dielectric layer, the dielectric layer providing a portion of the cavity-defining surface. The touch mode capacitance may be connected in parallel with the particular circuits completed by the electrical contact between the membrane and the particular ones of the plurality of switch electrodes.

Another aspect of the invention provides a microelectromechanical (MEMS) device comprising: a cavity-defining surface which defines a cavity, the cavity-defining surface comprising a plurality of electrically conductive surface elements; a channel that provides fluid communication with the cavity, the channel comprising a Tesla valve for permitting fluid flow in a first direction out of the cavity and through the channel while impeding fluid flow through channel into the cavity in a second direction opposed to the first direction. The channel is sealed during fabrication of the device to prevent ingress of material into the cavity.

The channel may be sealed by sealing material applied to the device.

The channel may be sealed by sealing material applied to the device in a vacuum environment to thereby vacuum seal the cavity by sealing the channel.

The sealing material may be applied using a conformal coating process. The sealing material may be applied using a vapor deposition process. The sealing material may be applied using a conformal vapor deposition process.

The channel may be shaped to provide: one or more dead-end paths; one or more circuitous path shapes; and/or one or more serpentine (S-shaped) channel shapes.

The cavity may be fabricated by extracting an etched sacrificial layer through the channel in the first direction prior to the channel being sealed.

The cavity-defining surface may comprise a plurality of electrically conductive surface elements.

The plurality of electrically conductive surface elements may comprise a membrane electrode provided by a membrane element. The membrane electrode may be deformable into the cavity.

The plurality of electrically conductive surface elements may comprise one or more static switch electrodes provided by one or more corresponding switch elements. The one or more static switch electrodes may be located on a portion of the cavity-defining surface generally opposed to the membrane electrode. The membrane electrode may be deformable across the cavity to make electrical contact between the membrane electrode and the one or more switch electrodes.

The one or more static switch electrodes may comprise a plurality of static switch electrodes. The plurality of static switch electrodes may be located in such a manner that an amount of deformation of the membrane electrode is positively correlated with a number of the plurality of switch electrodes with which the membrane electrode makes electrical contact.

Electrical contact between the membrane and a particular one of the one or more switch electrodes may complete a corresponding particular circuit. The corresponding particular circuit may comprise a corresponding particular circuit element.

The particular circuit element may comprise a discrete capacitive element. The particular circuit element may comprise at least one of: one or more capacitive elements, one or more inductive elements, one or more resistive elements, one or more solid state transistors, one or more solid state diodes, one or more resonating circuit elements, one or more power sources and one or more electrically activated switches.

The particular circuits completed by the electrical contact between the membrane and the particular ones of the plurality of switch electrodes may be connected in parallel with one another.

The membrane may be deformable under an influence of at least one of: external pressure and heat. An amount of deformation of the membrane may be positively correlated with an amount of the external pressure or heat.

The device may comprise a static touch-mode electrode on a side of the cavity generally opposite the membrane electrode. A touch-mode capacitance provided by the membrane electrode and the touch-mode electrode may be positively correlated with the amount of deformation of the membrane electrode. The touch-mode electrode may be coated with a dielectric layer, the dielectric layer providing a portion of the cavity-defining surface. The touch mode capacitance may be connected in parallel with the particular circuits completed by the electrical contact between the membrane and the particular ones of the plurality of switch electrodes.

Another aspect of the invention provides a microelectromechanical (MEMS) device comprising: a cavity-defining surface which defines a cavity, the cavity-defining surface comprising a plurality of electrically conductive surface elements. The plurality of electrically conductive surface elements comprising: a membrane electrode provided by a membrane element, the membrane electrode deformable into the cavity; and one or more static switch electrodes provided by one or more corresponding switch elements, the one or more static switch electrodes located on a portion of the cavity-defining surface generally opposed to the membrane electrode. The membrane electrode is deformable between a first configuration where the membrane electrode is spaced apart from the one or more switch electrodes and a second configuration wherein the membrane is deformed across the cavity to make electrical contact between the membrane electrode and at least one of the one or more switch electrodes. Electrical contact between the membrane and a particular one of the one or more switch electrodes completes a corresponding particular circuit, the corresponding particular circuit comprising a corresponding particular circuit element.

The one or more static switch electrodes may comprise a plurality of static switch electrodes. The plurality of static switch electrodes may be located in such a manner that an amount of deformation of the membrane electrode is positively correlated with a number of the plurality of switch electrodes with which the membrane electrode makes electrical contact.

The particular circuit element may comprise a discrete capacitive element. The particular circuit element may comprise at least one of: one or more capacitive elements, one or more inductive elements, one or more resistive elements, one or more solid state transistors, one or more solid state diodes, one or more resonating circuit elements, one or more power sources and one or more electrically activated switches.

The particular circuits completed by the electrical contact between the membrane and the particular ones of the plurality of switch electrodes may be connected in parallel with one another.

The membrane may be deformable under an influence of at least one of: external pressure and heat. An amount of deformation of the membrane may be positively correlated with an amount of the external pressure or heat.

The device may comprise a static touch-mode electrode on a side of the cavity generally opposite the membrane electrode. A touch-mode capacitance provided by the membrane electrode and the touch-mode electrode may be positively correlated with the amount of deformation of the membrane electrode. The touch-mode electrode may be coated with a dielectric layer, the dielectric layer providing a portion of the cavity-defining surface. The touch mode capacitance may be connected in parallel with the particular circuits completed by the electrical contact between the membrane and the particular ones of the plurality of switch electrodes.

The device may comprise a channel that provides fluid communication with the cavity, the channel comprising a Tesla valve for permitting fluid flow in a first direction out of the cavity and through the channel while impeding fluid flow through channel into the cavity in a second direction opposed to the first direction. The channel may be sealed during fabrication of the device to prevent ingress of material into the cavity.

The channel may be sealed by sealing material applied to the device.

The channel may be sealed by sealing material applied to the device in a vacuum environment to thereby vacuum seal the cavity by sealing the channel.

The sealing material may be applied using a conformal coating process. The sealing material may be applied using a vapor deposition process. The sealing material may be applied using a conformal vapor deposition process.

The channel may be shaped to provide: one or more dead-end paths; one or more circuitous path shapes; and/or one or more serpentine (S-shaped) channel shapes.

The cavity may be fabricated by extracting an etched sacrificial layer through the channel in the first direction prior to the channel being sealed.

Other aspects of the invention provide apparatus having any new and inventive feature, combination of features, or sub-combination of features as described herein.

Other aspects of the invention provide methods having any new and inventive steps, acts, combination of steps and/or acts or sub-combination of steps and/or acts as described herein.

Further aspects and example embodiments are illustrated in the accompanying drawings and/or described in the following description.

### BRIEF DESCRIPTION OF THE DRAWINGS

The accompanying drawings illustrate non-limiting example embodiments of the invention.

FIG. 1A is a schematic cross-sectional view of a micro-fabricated device according to a particular embodiment.

FIG. 1B is a schematic cross-sectional view of the FIG. 1A device in a second configuration where electrical contact is made between a membrane electrode and a switch electrode to thereby complete a circuit.

FIG. 1C is a schematic top view of the FIG. 1A device with the coating layer, membrane element and touch-mode dielectric layer removed to show the switch electrodes and a touch-mode electrode and also schematically depicting circuit elements connected to the switch electrodes and channels incorporating Tesla valves which are used to create and to seal the cavity of the device.

FIG. 1D is a schematic illustration of a channel incorporating a Tesla valve according to a particular embodiment that is suitable for use with the FIG. 1A device.

FIG. 1E is a circuit diagram of the FIG. 1A device in the particular case where the circuit elements are capacitors.

FIGS. 2A-2H (collectively, FIG. 2) schematically depict the process flow (various stages) in the microfabrication of the FIG. 1A device according to a particular embodiment.

FIGS. 3A-3D (collectively, FIG. 3) show various representations of a micro-fabricated device according to another example embodiment.

FIGS. 4A-4H (collectively, FIG. 4) schematically depict cross-sectional views of various stages in the microfabrication of the FIG. 3 device according to a particular embodiment.

FIGS. 5A-5F (collectively, FIG. 5) schematically depict three-dimension views of the process flow (various stages) in the microfabrication of the FIG. 3 device according to an example embodiment.

FIGS. 6A and 6B (collectively, FIG. 6) are schematic diagrams of experimental setups used to assess the performance of a capacitance-based pressure sensor incorporating one or more of the FIG. 3 device(s) according to an example embodiment.

FIG. 7A shows a plot of the capacitance measurement of the FIG. 6 sensor as a function of pressure according to an example embodiment. FIG. 7B shows an enlarged view of one segment of the FIG. 7A plot with a linear fit according to an example embodiment.

### DETAILED DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive sense.

Aspects of the invention provides methods for fabricating micro-fabricated devices comprising a cavity-defining surface which defines a cavity. Particular methods comprise: fabricating a channel that provides fluid communication with the cavity, the channel comprising a Tesla valve for permitting fluid flow in a first direction out of the cavity and through the channel while impeding fluid flow through channel into the cavity in a second direction opposed to the first direction; and applying a sealing material to the device (e.g. using a conformal coating which may be applied by a suitable conformal coating technique, such as a conformal vapor deposition technique, where the sealing material has solidifies or is caused to solidify on the channel defining surfaces) to thereby seal the channel. Applying the sealing material may comprise introducing the sealing material to the channel, in such a manner that the sealing material solidifies on the channel-defining surface(s) of the channel-defining wall(s), is caused to solidify on the channel-defining surface(s) or otherwise bonds or sticks to the channel-defining surface(s) and the sealing material is prevented from reaching the cavity at least in part by the action of the Tesla valve.

Other aspects of the invention provide microelectromechanical (MEMS) devices comprising: a cavity-defining surface which defines a cavity. The cavity-defining surface comprises a plurality of electrically conductive surface elements. The plurality of electrically conductive surface elements comprises: a membrane electrode provided by a membrane element, the membrane electrode deformable into the cavity; and one or more static switch electrodes provided by one or more corresponding switch elements, the one or more static switch electrodes located on a portion of the cavity-defining surface generally opposed to the membrane electrode. The membrane electrode is deformable between a first configuration where the membrane electrode is spaced apart from the one or more switch electrodes and a second configuration wherein the membrane is deformed across the cavity to make electrical contact between the membrane electrode and the one or more switch electrodes. Electrical contact between the membrane and a particular one of the one or more switch electrodes completes a corresponding particular circuit comprising a corresponding particular circuit element.

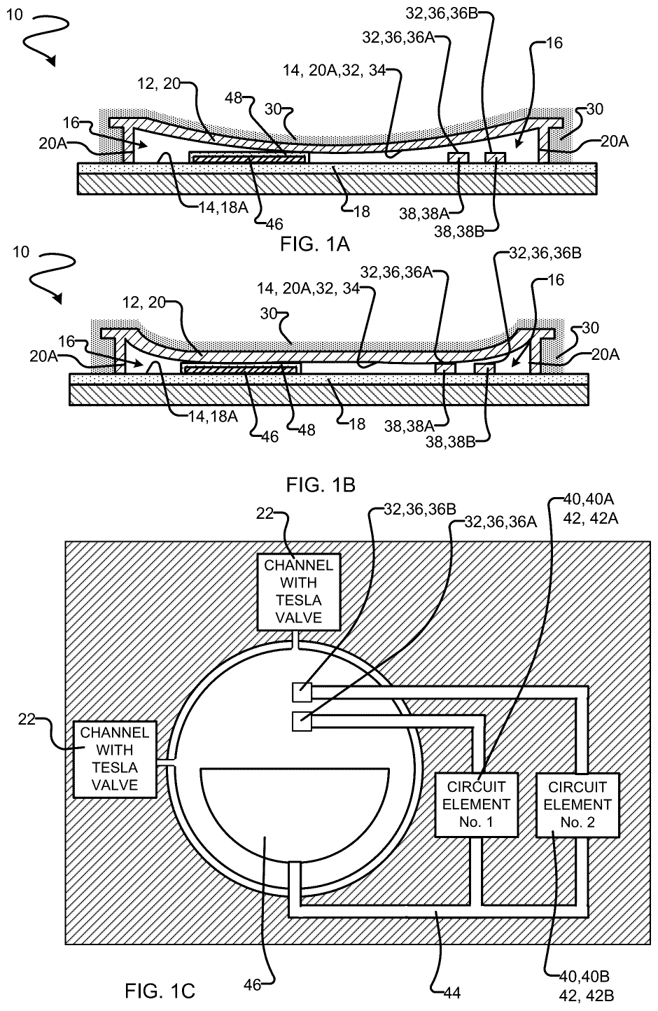

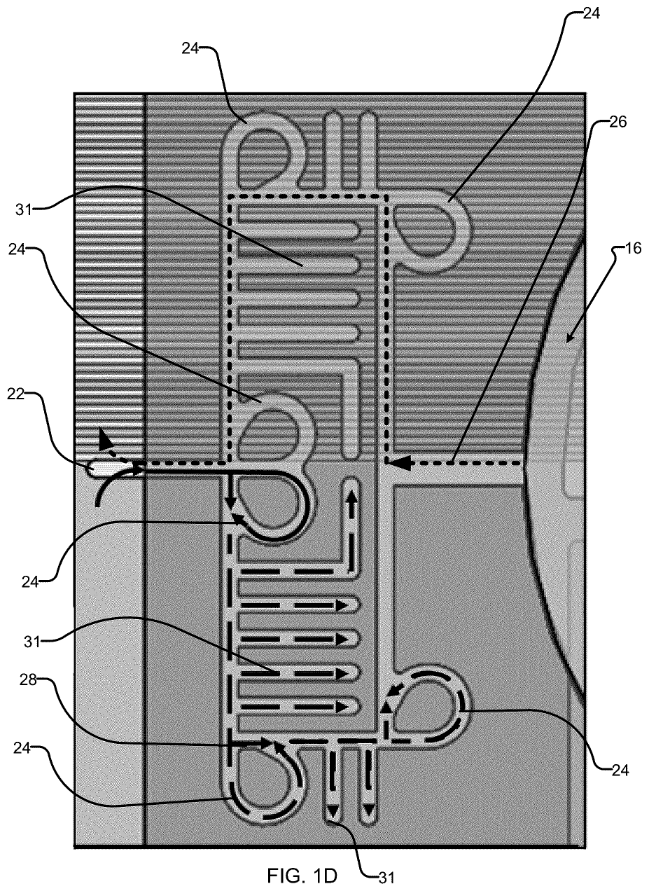

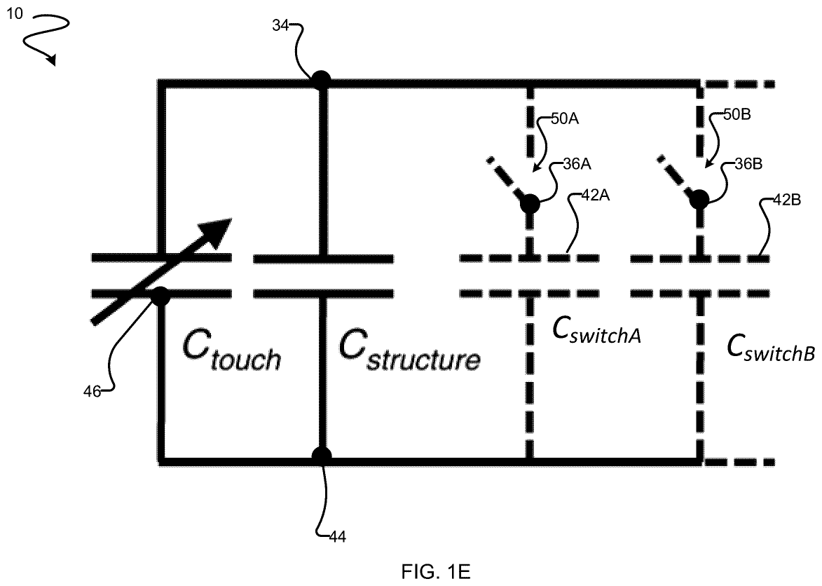

FIGS. 1A-1E (collectively, FIG. 1) show various representations relating to a micro-fabricated device 10 according to a particular embodiment. Device 10 of the FIG. 1 embodiment is a microelectromechanical (MEMS) device 10 comprising a moving membrane element 12 (for brevity, membrane 12), although device 10 need not necessarily be a MEMS device. In general, device 10 could comprise any micro-fabricated device—e.g. devices having features of micrometer scale or smaller, which may be fabricated on silicon and/or other semiconductors or other substrates, such as glass, ceramic(s) and/or the like. Device 10 comprises a cavity-defining surface 14 which defines a cavity 16. As explained in more detail below, cavity 16 may be sealed during the fabrication of device 10. In some embodiments, cavity 16 may enclose a fluid (e.g. air, other gas and/or liquid). In some embodiments, cavity 16 may be evacuated, in which case cavity 16 may be vacuum sealed.

Cavity 16 and cavity-defining surface 14 may generally be fabricated using any suitable technique. In the particular case of the illustrated embodiment and as explained in more detail below, cavity 16 may be fabricated by depositing a sacrificial layer (not shown in FIG. 1) on a substrate 18, depositing a cover layer 20 (e.g. membrane 12) to cover the sacrificial layer and then removing the sacrificial layer through one or more channels 22 to leave behind cavity 16 defined by a cavity-defining surface 14. Cavity-defining surface 14 may include one or more surfaces 18A of substrate 18 (on which the sacrificial layer is formed) and one or more surfaces 20A of cover layer 20 (which covered the sacrificial layer prior to its removal). Typically, removal of the sacrificial layer comprises introducing an etchant (e.g. an acidic liquid etchant—not shown) to the sacrificial layer (i.e. bringing the etchant into to contact with the sacrificial layer) via channels 22. The etchant breaks down (e.g. dissolves) the sacrificial layer and the material of the sacrificial layer is removed from cavity 16 (along with the etchant) via channels 22. The material of the sacrificial layer may be removed from cavity 16 (along with the etchant) by diffusion, although other processes (e.g. the application of a pressure differential and/or rinsing with other chemicals (e.g. isopropyl alcohol and/or the like)) could be used to help remove the sacrificial layer in solution. In some embodiments, the etchant used is a mixture of NMP (n-methyl pyrrolidinone) (also known as 1165 remover) and acetone (which may be suitably highly selective for particular types of sacrificial layer materials—e.g. LOR30C), although, in general, any suitable etchant and any suitable etching technique (e.g. vapor HF etching or other forms of vapor etching) may be used to remove the sacrificial layer and thereby form cavity 16.

Channels 22 provide fluid communication with cavity 16 to allow introduction and removal of the sacrificial layer as discussed above. In some embodiments, at least one channel 22 comprises one or more valves with no moving parts. An example channel 22 is shown in FIG. 1D. Channels 22 comprise one or more Tesla valves 24, which permit fluid flow in a first direction 26 out of cavity 16 and through channel 22 while impeding fluid flow through channel 22 in a second direction 28 opposed to first direction 26. In the illustration of FIG. 1D, flow in the first direction 26 is indicated using lines with short dashes in the upper half of the illustrated channel 22 while flow in the second direction 28 is indicated using lines with longer dashes in the lower half of the illustrated channel 22. Flow in the first direction 26 through channel 22 is that path through which the sacrificial layer 110 (described in more detail below) is released to form cavity 16. Flow of coating layer 30 (described in more detail below) is impeded by each Tesla valve 24 in channel 22 so that the material of coating layer is prevented from reaching cavity 16 and seals channel 22 and cavity 16. It should be noted that the illustration of flow in the first direction 26 in the top portion of channel 22 (in the FIG. 1D view) and flow in the second direction 28 in the bottom portion of channel 22 (in the FIG. 1D view) is merely for illustrative purposes. In practice, flow in both directions occurs in both portions of channel 22.

While fluids are impeded as they flow through channel 22 in the second direction 28 (i.e. from outside of device 10 toward cavity 16), some materials under some conditions will flow through channel 22 in the second direction 28 to ultimately reach cavity 16. This is the case, for example, where etchant is introduced via channel 22 into contact with the sacrificial layer 110 (described in more detail below), to dissolve the sacrificial layer 110 and to thereby create cavity 16. However, for some materials in some conditions, such as sealing materials 30 deposited onto the surfaces of device 10 in a vapor or gaseous phase (e.g. in conformal vapor deposition techniques), channel 22 (and their Tesla valves) impede the flow of such materials in the second direction 28 sufficiently to prevent the travel of such materials through channel 22 in second direction 28 and to prevent such materials from reaching cavity 16. In some such embodiments, the sealing material 30 solidifies on the channel-defining surface(s) of the channel-defining wall(s) or otherwise bonds or sticks to the channel-defining surface(s) of channel 22 to thereby seal cavity 16.

Device 10 of the illustrated embodiment is sealed with a sealing material which provides a coating layer 30. Coating layer 30 may comprise a conformal coating which may be applied by any suitable technique, such as, by way of non-limiting example, vapor deposition (e.g. conformal chemical or plasma-enhanced vapor deposition) and/or the like. In some embodiments, the coating layer 30 may comprise a suitable dielectric polymer, such as Parylene C, for example, as well as other types of Parylene (N, D, HT, etc.). Advantageously, Parylene C is biocompatible. Other sealing materials that could be applied to provide coating layer 30 include, without limitation, any material that can be deposited by conformal vapor deposition, such as silicon compounds (e.g. polycrystalline silicon, silicon oxides such as SiO₂ and/or the like, silicon nitride, etc.), phosphosilicate glass (PSG), tungsten, diamond, carbon, fluorocarbons organofluorines, nitrides and/or the like. Coating layer 30 provides device 10 with protection (e.g. against physical contact and/or moisture) and/or electrical insulation. Coating layer 30 may also seal channels 22, thereby effectively sealing cavity 16. In some embodiments, coating layer 30 may be applied in a vacuum environment to provide cavity 16 with a vacuum seal. During deposition, the sealing material of coating layer 30 may travel into channels 22 and is prevented from reaching cavity 16 by Tesla valves 24, which, as discussed above, impede the flow of fluids in the second direction (from an outside of device 10, through channels 22 and into cavity 16). The sealing material of coating layer 30 is trapped in channels 22 by Tesla valves 24 and deposited onto the channel-defining surface(s) of the walls that define channels 22, until channels 22 and cavity 16 are sealed. Advantageously, Tesla valves 24 in channels 22 prevent the sealing material of coating layer 30 from reaching cavity 16, so that the sealing material does not impact the performance of device 10 (described in more detail below). In particular, the shapes of channels 22 (including their respective Tesla valves) may be designed (e.g. in conjunction with the conditions and materials selected for deposition of coating layer 30) such that the impediment to fluid flow caused by Tesla valves is sufficient to prevent the sealing material of coating layer 30 from reaching cavity 16.

As shown in FIG. 1D, channels 22 may also comprise one or more dead-end paths 31, which may be provided at locations in channels 22 between, upstream of and/or downstream from, Tesla valves 24. Advantageously, for a given on-wafer (or on-chip) surface area, dead-end paths 31 may provide increased channel surface area (e.g. the surface area of the channel-defining surface(s) of the channel-defining wall(s) of channels 22) to ensure that any sealing material of coating 30 that escapes Tesla valves 24 has a higher probability of adhering to the channel-defining surface(s) of channels 22 prior to reaching cavity 16. In some embodiments, channels 22 comprise other additional or alternative channel shapes that provide increased surface area of the channel-defining surface for a given on-wafer surface area. Such additional or alternative channel shapes include, for example, circuitous path shapes, serpentine (S-shaped) path shapes and/or the like.

In the particular case of device 10 of the FIG. 1 embodiment, cavity-defining surface 14 comprises one or more electrically conductive surface elements 32 (shown in FIGS. 1A-C). Electrically conductive surface elements 32 may comprise portions of cavity-defining surface 14 that are electrically conductive. In the FIG. 1 embodiment, electrically conductive surface elements 32 comprise: the cavity-defining surface of membrane 12 which provides a membrane electrode 34 and one or more switch electrodes 36 on a side of cavity 16 generally opposed to membrane electrode 34. In the case of the illustrated embodiment, switch electrodes 36 comprise a plurality of switch electrodes 36A and 36B (collectively, switch electrodes 36), which are provided on the cavity-defining surfaces of switch elements 38A, 38B (collectively, switch elements 38).

In the case of the illustrated FIG. 1 embodiment, membrane 12 is deformable into cavity 16, which can be seen, for example, by comparing FIGS. 1A and 1B (which show two different configurations of device 10). Membrane 12 may be deformable into cavity 16 under the influence of pressure to provide a pressure sensing functionality discussed in more detail below. Comparing FIGS. 1A and 1B, it can be seen that, in the configuration of FIG. 1A, membrane 12 (and more particularly membrane electrode 34) is spaced apart from switch electrodes 36, but, when membrane 12 is further deformed as is the case in FIG. 1B, membrane electrode 34 may come into physical contact with (and may make electrical (ohmic) contact with) one or more switch electrodes 36. Specifically, in the FIG. 1B configuration, membrane electrode 34 makes physical and electrical contact with switch electrode 36A (although no contact is made, in the FIG. 1B configuration, with switch electrode 36B). If membrane 12 is further deformed into cavity 16 (a configuration not shown in the illustrated views), membrane electrode 34 may make physical and electrical (ohmic) contact with switch electrode 36B. In some embodiments, the amount of deformation membrane 12 (and/or membrane electrode 34) is positively correlated with a number of the plurality of switch electrodes 36 with which membrane electrode 34 makes electrical (ohmic) contact. For example, where membrane 12 deforms under the influence of pressure, the amount of pressure may be positively correlated with the amount of deformation of membrane 12 (and/or membrane electrode 34) which is in turn positively correlated with a number of the plurality of switch electrodes 36 with which membrane electrode 34 makes electrical (ohmic) contact. Membrane 12 may be deformable into cavity 16 (e.g. into different configurations similar to the ones discussed above) under the influence of physical phenomenon other than or in addition to pressure to provide different sensing functionality. By way of non-limiting example, by creating membrane 12 and the substrate under cavity 16 from materials having different rates of thermal expansion, membrane 12 may deform into cavity under the influence of heat. In some such embodiments, the amount of heat may be positively correlated with the amount of deformation of membrane 12 (and membrane electrode 34) which is in turn positively correlated with a number of the plurality of switch electrodes 36 with which membrane electrode 34 makes electrical (ohmic) contact.

The electrical contact (or lack of electrical contact) between membrane electrode 34 and switch electrode(s) 36 may provide a switching functionality. In particular, where electrical contact is made between membrane electrode 34 and a particular one of switch electrodes 36, a corresponding circuit may be completed (i.e. an electrical switch may be closed) to permit current flow between membrane electrode 34 and the particular one of switch electrodes 36. In contrast, where there is no electrical contact between membrane electrode 34 and the particular one of switch electrodes 36, current is prevented from flowing therebetween and the circuit is open (i.e. the electrical switch is opened). As shown in FIG. 1C, each one of switch electrodes 36 may be connected to a corresponding circuit 40 (circuits 40A, 40B, in the FIG. 1 embodiment) and each such circuit 40 may comprises one or more corresponding circuit elements 42 (circuit elements 42A, 42B, in the FIG. 1 embodiment). In the illustrated embodiment shown in FIG. 1C, circuit elements 42 are shown as being connected in parallel with one another (but this is not necessary) and circuits 40 share a common node 44 (but this is not necessary).

In some particular embodiments, circuit elements 42 comprise capacitive circuit elements. In some embodiments, circuit elements 42 may comprise capacitive elements, inductive elements, resistive elements, transistors (e.g. solid state transistors), diodes (e.g. solid state diodes), resonating circuit elements, power sources, electronically controlled switches and/or the like, combinations of these types of elements and/or the like.

In the particular case of the FIG. 1 embodiment, device 10 comprises a touch-mode electrode 46 on a side of cavity 16 generally opposed to membrane electrode 34. Together membrane electrode 34 and touch-mode electrode 46 provide a touch-mode capacitance C_{touch_tot}. It will be appreciated that the touch-mode capacitance C_{touch_tot} is positively correlated with the amount of deformation of membrane 12 (and membrane electrode 34). More specifically, as the deformation of membrane 12 increases (e.g. from the FIG. 1A configuration to the FIG. 1B configuration), the amount of surface area of touch-mode electrode 46 and membrane electrode 34 that are in proximity to one another increases and the proximity of these surface areas may also increase and, consequently, the touch-mode capacitance Crouch tot increases correspondingly.

In the illustrated embodiment, touch-mode electrode 46 is coated with a touch-mode dielectric layer 48 which permits physical contact (between membrane electrode 34 and touch-mode dielectric layer 48) while preventing electrical (ohmic) contact between membrane electrode 34 and touch-mode electrode 46. Touch-mode dielectric layer 48 permits a “touch-mode” operation. For example, in some such configurations, membrane electrode 34 may be configured (e.g. sized and/or shaped) such that membrane 34 is just barely in contact with touch-mode dielectric layer 48 at a low extreme of expected pressure and is fully in contact with touch-mode dielectric layer 48 at a high extreme of expected pressure. Touch-mode dielectric layer 48 and touch-mode operation are not strictly necessary. In some embodiments, the “touch-mode” capacitance C_{touch_tot} may vary merely by bringing variable amounts of surface area of membrane electrode 34 into proximity with touch-mode electrode 48 without actual physical contact or touching. In some embodiments, touch-mode electrode 46 is not necessary.

FIG. 1E shows an equivalent circuit diagram of device 10 in the particular case where circuit elements 42 are capacitors, which respectively provide capacitances C_{switchA} and C_{switchB}. The total capacitance Cₛ(p) of device 10 may be a function of pressure p and may be given by:

Cₛ(p)=C_{touch_tot}(p)+C_{switchA}(p)+C_{switchB}(p)+C_{structural} (1)

where the total capacitance C_{touch_tot}(p) provided by the interaction of membrane electrode 34 and touch-mode electrode 46 may be expressed as:

C_{touch_tot}(p)=C_{touch}(p)+C_{non-contact}(p) (1A)

where:
C_{touch}(p) is the portion of the touch-mode capacitance attributable to the portion of membrane electrode 34 which is in contact with touch-mode dielectric layer 48;
C_{non-contact}(p) is the portion of the touch-mode capacitance attributable to interaction of the portion of membrane electrode 34 not in contact with touch-mode dielectric layer 48;
C_{structural} is the combined parasitic capacitance from all of the other structural parts of device 10;
C_{switchA}(p) is the capacitance of capacitive circuit element 42A which has a value of 0 when switch 50A is open and a non-zero value when switch 50A is closed (corresponding to membrane electrode 34 being in electrical contact with switch electrode 36A); and
C_{switchB}(p) is the capacitance of capacitive circuit element 42B which has a value of 0 when switch 50B is open and a non-zero value when switch 50B is closed (corresponding to membrane electrode 34 being in electrical contact with switch electrode 36B).

It will be appreciated that the capacitance C_{touch_tot}(p) is positively correlated with pressure—i.e. C_{touch_tot}(p) increases as pressure increases (and the deformation of membrane 12 and membrane electrode 34 (e.g. across cavity 16) increases). This change in capacitance C_{touch_tot}(p) may be relatively smoothly varying. In contrast, due to the parallel nature of the connection between capacitive circuit elements 42 (between membrane 34) and node 44, when the deformation of membrane 12 (or membrane electrode 34) brings membrane electrode 34 into electrical contact with one of switch electrodes 36A, 36B (i.e. closing one of switches 50A, 50B), there is a corresponding step in capacitance as C_{switchA}(p) or C_{switchB}(p) is added to the total capacitance Cₛ(p). In this sense, device 10 may be considered to implement and may be referred to herein as a “switch mode” capacitive pressure sensor.

The number of switch electrodes 36 and corresponding circuits 40 and circuit elements 42 in the illustrated embodiment of device 10 is shown as two for brevity and simplicity. However, devices according to particular embodiments, may generally be provided with any suitable number of switch electrodes 36 and corresponding circuits 40 and circuit elements 42, in which case equation (1) can be replaced with:

$${C}_{s} ( p ) = {C}_{touch\_tot} ( p ) + {\sum }_{i = 0}^{n ( p )} {C}_{switch\_i} + {C}_{structural} \qquad ( 1 )$$

where:
n(p) is the number of closed switches 50 (i.e. the number of switch electrodes 36 that are in contact with deformable membrane electrode 34); and
C_{switch_i} is the capacitance of the i^{th} capacitor 42.
   It will be appreciated that C_{switch_i} may be the same for each capacitor 42 and/or may be different for each capacitor 42 and/or may be same for different groups of capacitors 42 and different for other groups of capacitors 42.

It will be appreciated that for the functionality of the switch-mode capacitive pressure sensor described above, it is desirable that there not be any contaminants (dielectric or conductive) in cavity 16, as such contaminants cold adversely impact the electrical characteristics (e.g. capacitance) of device 10 or the physical characteristics (e.g. deformation of membrane 12 and/or space in cavity 16 for membrane 12 to deform) of device 10. In particular, there is a desire to coat device 10 with coating layer 30 and/or to seal cavity 16, while preventing the sealing material (e.g. of coating layer 30) from reaching cavity 16. Such functionality may be achieved by providing channels 22 with Tesla valves 24. Such functionality may be achieved by applying coating layer 30 using a conformal coating technique (e.g. conformal vapor deposition) where the material of coating layer solidifies on the channel-defining surface(s) of the channel-defining wall(s), is caused to solidify on the channel-defining surface(s) or otherwise bonds or sticks to the channel-defining surface(s) of channels 22 to seal cavity 16.

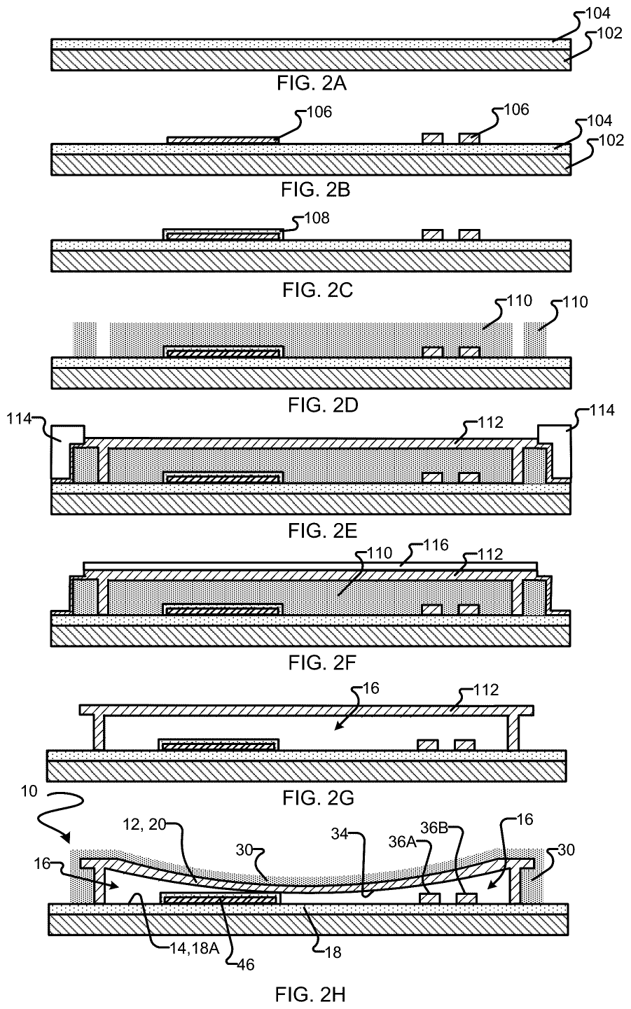

FIG. 2 schematically depicts a method for microfabrication of device 10 according to a particular embodiment. Device 10 may be fabricated on a silicon wafer 102 with an oxide (SiO₂) layer 104 as shown in FIG. 2A using a number of patterning steps involving UV lithography. Next, fixed electrode layer 106 is deposited as shown in FIG. 2B. In one particular embodiment, fixed electrode layer 106 is deposited using Ti/Au e-beam evaporation (10/100 nm) and patterned at 4-μm resolution with a bilayer lift-off process using LOR3A (425 nm baked at 200° C. for 5 min) and S1813 (1.6 μm soft baked at 115° C. for 1 min) photoresists. Fixed electrode layer 106 may provide optional touch-mode electrode 46 and switch electrodes 36 described elsewhere herein. Bilayer lift-off may involve undercutting the LOR3A photoresist as it isotopically dissolves during the S1813 development. Next, a dielectric layer 108 is deposited and patterned as shown in FIG. 2C to provide touch-mode dielectric layer 48 described elsewhere herein. In one particular embodiment, applying dielectric layer 108 comprises depositing a Si₃N₄ film using plasma-enhanced chemical vapor deposition and patterning dielectric layer 108 using an S1813 photoresist and a CF₄/O₂ reactive ion etching timed to minimize etching of the thermal oxide layer 104.

In FIG. 2D, a sacrificial layer 110 is deposited. In some embodiments, sacrificial layer 110 may be deposited by spin coating, although any suitable technique may be used for the application of sacrificial layer 110. In some embodiments, sacrificial layer 110 is deposited by spin-coating a bilayer of LOR30C and S1805 photoresists. The bilayer may be UV exposed (e.g. to provide the patterning for what will become cavity 16 and channels 22) and developed upside down to increase the likelihood that LOR30C undercut has a positive sidewall profile underneath the S1805, which assists with the sputtering step described below. Sacrificial layer 110 may be finalized with an acetone dip which dissolves the S1805 while leaving the LOR30C as sacrificial layer 110.

In FIG. 2E, membrane layer 112 is formed atop sacrificial layer 110. In some embodiments, membrane layer 112 may be deposited by first sputtering Ti/Au to provide a conformal coating that seals the previous layers and protects sacrificial layer 110 from a subsequent development process. This sputtered layer may serve as a seed layer for a subsequent electroplating step (e.g. Au electroplating) to complete membrane layer 112. The electroplating step may comprise forming an electroplating mold 114 using a UV-patterned photoresist (e.g. AZ P4620) and then electroplating in a suitable electroplating bath (e.g. potassium aurocyanide) to obtain a desired membrane thickness. Preferably, the time spent in the electroplating bath is sufficiently short to avoid the deterioration of electroplating mold 114. Electroplating mold 114 may then be removed with suitable photoresist remover (e.g. NMP (n-methyl pyrrolidinone, 1165 remover)).

In FIG. 2F, membrane layer 112 is patterned to form the final structure of membrane 12 of device 10 and to provide access to sacrificial layer 110 and the patterned features which will become channels 22 and cavity 216. This FIG. 2F step may comprise applying another layer 116 of suitable photoresist (e.g. AZ P4620) which may be used as protection for an etch of the metal in membrane layer 112. In one particular embodiment, this etching step may comprise an etch of gold using potassium iodide and a Ti etch using hydrofluoric acid.

In FIG. 2G, photoresist layer 116 is stripped using a suitable photoresist remover (e.g. a mixture of acetone and 1165 remover). The same mixture or some other suitable solvent may be used to dissolve sacrificial layer 110 through channels 22. Channels 22 are not shown in the illustrated cross-sections of FIG. 2. The device 10 can then be suitably connected (e.g. wire bonded) to printed circuit boards and/or chip carriers or the like (not shown).

In FIG. 2H, device 10 is coated with a sealing material (e.g. a dielectric sealing material or other suitable coating material) which provides coating layer 30. Coating layer 30 comprises a conformal coating which may be applied by any suitable technique, such as, by way of non-limiting example, vapor deposition (e.g. conformal chemical or plasma-enhanced vapor deposition) and/or the like. In some such embodiments, the sealing material of coating 30 solidifies on the channel-defining surface(s) of the channel-defining wall(s), is caused to solidify on the channel-defining surface(s) or otherwise bonds or sticks to the channel-defining surface(s) of channels 22, thereby sealing channels 22 and effectively sealing cavity 16. In some embodiments, the coating layer 30 may comprise a suitable dielectric polymer, such as Parylene C, for example, as well as other types of Parylene (N, D, HT, etc.). Advantageously, Parylene C is biocompatible. Other sealing materials that could be applied to provide coating layer 30 include, without limitation, any material that can be deposited by conformal vapor deposition, such as silicon compounds (e.g. polycrystalline silicon, silicon oxides such as SiO₂ and/or the like, silicon nitride, etc.), phosphosilicate glass (PSG), tungsten, diamond, carbon, fluorocarbons organofluorines, nitrides and/or the like). Coating layer 30 provides device 10 with protection (e.g. against physical contact and/or moisture) and/or electrical insulation. In some embodiments, coating layer 30 may be applied in a vacuum environment to provide cavity 16 with a vacuum seal. During deposition, the sealing material of coating layer 30 may travel into channels 22 and is prevented from reaching cavity 16 by Tesla valves 24. The sealing material of coating layer 30 is trapped in channels 22 by Tesla valves 24 and deposited onto the channel-defining surface(s) of the wall(s) that define channels 22 where it solidifies or is caused to solidify, until channels 22 and cavity 16 are sealed. Advantageously, Tesla valves 24 in channels 22 prevent the sealing material of coating layer 30 from reaching cavity 16, so that the sealing material does not impact the performance of device 10.

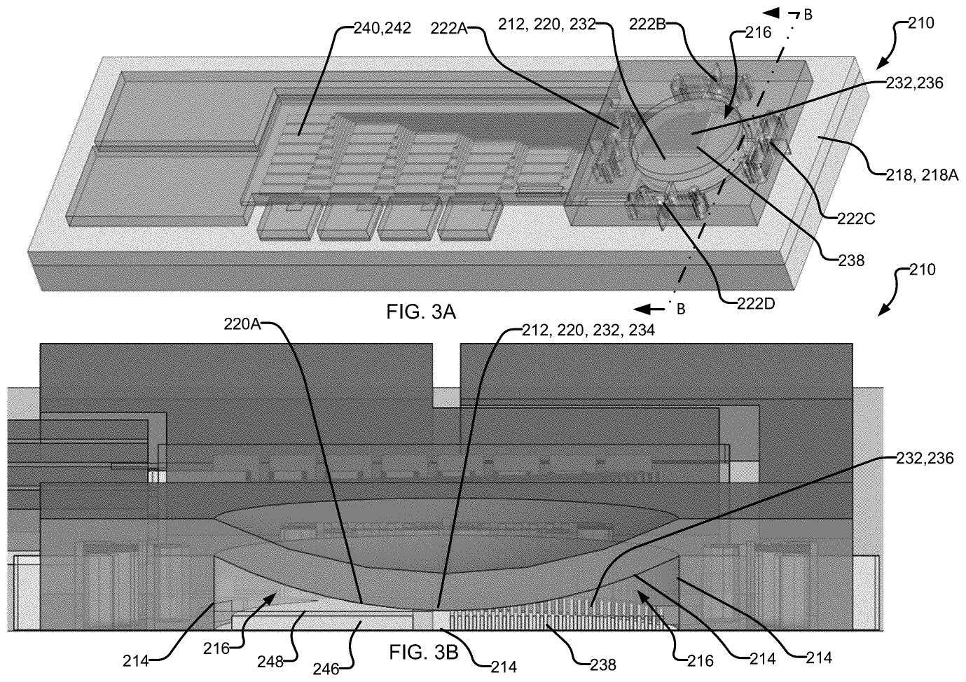

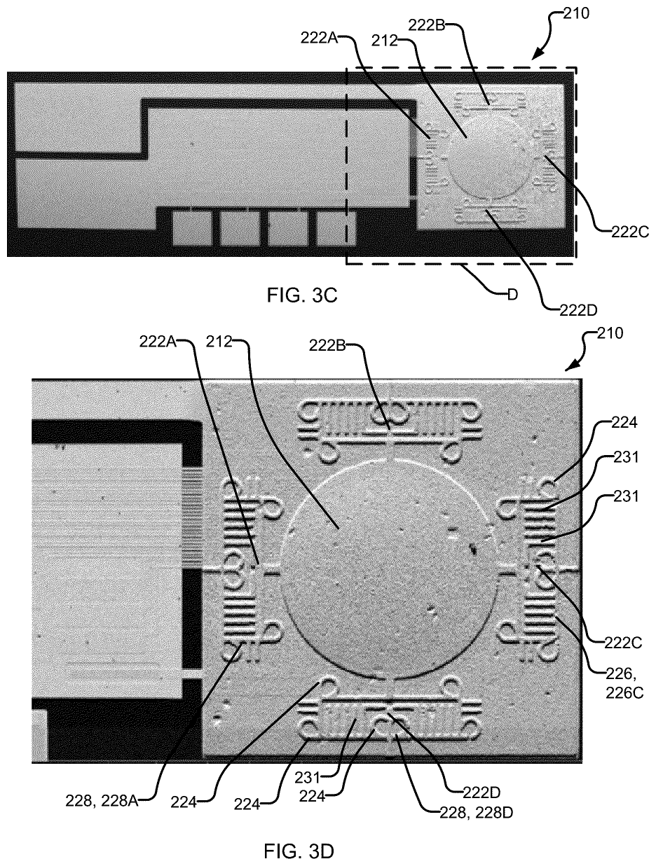

FIGS. 3A-3D (collectively, FIG. 3) show various representations relating to a micro-fabricated device 210 according to an example embodiment. FIG. 3A is schematic perspective view of micro-fabricated device 210. FIG. 3B is a cross-sectional view of micro-fabricated device 210 along lines B-B in FIG. 3A. FIG. 3C is a top plan view of a scanning electron microscope (SEM) image of micro-fabricated device 210 after cavity 216 is evacuated but before channels 222 are sealed according to a particular embodiment. FIG. 3D is a top plan view of a SEM image of a portion D of FIG. 3C showing an enlarged view of membrane 212 and channels 222A-D.

In many respects, device 210 is similar to device 10 and similar features of device 210 are assigned similar reference numerals to those of device 10, except that the features of device 210 are incremented by 200. Except as where otherwise noted, features of device 210 may be similar to those of corresponding features of device 10 and vice versa. Device 210 of the FIG. 3 embodiment is a MEMS device 210 comprising a moving membrane element 212 (for brevity, membrane 212), although device 210 need not necessarily be a MEMS device. In general, device 210 could comprise any micro-fabricated device—e.g. devices having features of micrometer scale or smaller, which may be fabricated on silicon and/or other semiconductors or other substrates, such as glass, ceramic(s) and/or the like. Device 210 comprises a cavity-defining surface 214 which defines a cavity 216. Cavity 216 may be sealed during the fabrication of device 210. In some embodiments, cavity 216 may enclose a fluid (e.g. air, other gas and/or liquid. In some embodiments, cavity 216 may be evacuated, in which case cavity 216 may be vacuum sealed.

Cavity 216 and cavity-defining surface 214 may generally be fabricated using any suitable technique. In the particular case of the illustrated embodiment, cavity 216 may be fabricated by depositing a sacrificial layer (not shown in FIG. 3) on a substrate 218 (shown in FIG. 3A), depositing a cover layer 220 (e.g. membrane 212) to cover the sacrificial layer and then removing the sacrificial layer through one or more channels 222A-D (collectively, “channels 222”, each of which may be similar to channel 22 illustrated in FIG. 1D and described above) to leave behind cavity 216 defined by cavity-defining surface 214. Cavity-defining surface 214 may include one or more surfaces 218A of substrate 218 (on which the sacrificial layer is formed) and one or more surfaces 220A (shown in FIG. 3b) of cover layer 220 (which covered the sacrificial layer prior to its removal). Typically, removal of the sacrificial layer comprises introducing an etchant (e.g. an acidic liquid etchant—not shown) to the sacrificial layer (i.e. bringing the etchant into to contact with the sacrificial layer) via channels 222. The etchant breaks down (e.g. dissolves) the sacrificial layer and the material of the sacrificial layer is remove from cavity 216 (along with the etchant) via channels 222. The material of the sacrificial layer may be removed from cavity 216 (along with the etchant) by diffusion, although other processes (e.g. the application of a pressure differential and/or rinsing with other chemicals (e.g. isopropyl alcohol and/or the like)) could be used to help remove the sacrificial layer in solution. In some embodiments, the etchant used is a mixture of NMP (n-methyl pyrrolidinone) (also known as 1165 remover) and acetone (which may be suitably highly selective for particular types of sacrificial layer materials—e.g. LOR30C), although, in general, any suitable etching technique (e.g. vapor HF etching or other forms of vapor etching) may be used to remove the sacrificial layer and thereby form cavity 216.

Channels 222 provide fluid communication with cavity 216 to allow introduction and removal of the sacrificial layer in manners similar to channel 22 of device 10 as discussed above. Channels 222 are shown in more detail in FIGS. 3C and 3D and operate in manner substantially similar to channel 22 described elsewhere herein in connection with FIG. 1D. Channels 222 comprise one or more Tesla valves 224, which permit fluid flow in a first direction out of cavity 216 and through channels 222 while impeding fluid flow through channels 222 in a second direction opposed to first direction. While fluids are impeded as they flow through channel 222 in the second direction (i.e. from outside of device 210 toward cavity 216), some materials under some conditions will flow through channel 222 in the second direction to ultimately reach cavity 216. This is the case, for example, where etchant is introduced via channel 222 into contact with the sacrificial layer, to dissolve the sacrificial layer and to thereby create cavity 216. However, for some materials in some conditions, such as sealing materials deposited onto the surfaces of device 210 in a vapor or gaseous phase (e.g. in conformal vapor deposition techniques), channel 222 (and their Tesla valves) impede the flow of such materials in the second direction sufficiently to prevent the travel of such materials through channel 222 and to prevent such materials from reaching cavity 216. In some such embodiments, the sealing material solidifies on the channel-defining surface(s) of the channel-defining wall(s), is caused to solidify on the channel-defining surface(s) or otherwise bonds or sticks to the channel-defining surface(s) to thereby seal cavity 216. Flow of coating layer 230 (described in more detail below) is impeded by each Tesla valve 224 in channel 222 so that the material of coating layer 230 is prevented from reaching cavity 216 and seals channel 222 and cavity 216.

As shown in FIG. 3D, channels 222 may also comprise one or more dead-end paths 231, which may be provided at locations in channels 222 between, upstream of and/or downstream from, Tesla valves 224. Advantageously, for a given on-wafer (or on-chip) surface area, dead-end paths 231 may provide increased channel surface area (e.g. total surface area of the channel-defining surface(s) of the channel-defining wall(s) of channels 222) to ensure that any sealing material that escapes Tesla valves 224 has a higher probability of adhering to the channel-defining surface(s) of channels 222 prior to reaching cavity 216.

In the particular case of device 210 of the FIG. 3 embodiment, cavity-defining surface 214 comprises one or more electrically conductive surface elements 232 (shown in FIG. 3B). Electrically conductive surface elements 232 may comprise portions of cavity-defining surface 214 that are electrically conductive. In the FIG. 3 embodiment, electrically conductive surface elements 232 comprise: the cavity-defining surface of membrane 212 which provides a membrane electrode 234 and one or more switch electrodes 236 on a side of cavity 216 generally opposed to membrane electrode 234. In some embodiments, one or more switch electrodes 236 comprise a plurality of switch electrodes which are provided on a corresponding plurality of cavity-defining surfaces of a corresponding plurality of switch elements 238. In the illustrated embodiment, device 210 comprises twenty-nine switch electrodes 236 provided on a corresponding twenty-nine cavity-defining surfaces of switch elements 238.

In some embodiments, switch elements 238 comprise switch leads that connect each switch electrode 236 to a corresponding circuit 240 and each such circuit 240 may comprise one or more corresponding circuit elements 242. In the illustrated embodiment shown in FIG. 3, circuit elements 242 comprise capacitive circuit elements. Specifically, in FIG. 3, device 210 comprises twenty-nine circuits 240 each corresponding to a switch electrode 236. In some embodiments, circuit elements 242 may comprise capacitive elements, inductive elements, resistive elements, transistors (e.g. solid state transistors), diodes (e.g. solid state diodes), resonating circuit elements, power sources, electronically controlled switches and/or the like, combinations of these types of elements and/or the like.

In the case of the illustrated FIG. 3 embodiment, membrane 212 is deformable into cavity 216, which can be seen, for example, in FIG. 3B. Membrane 212 may be deformable into cavity 216 under the influence of pressure to provide a pressure sensing functionality. In FIG. 3B, portions of membrane 212 (and more particularly membrane electrode 234) are spaced apart from some of switch electrodes 236 and portions of membrane 212 are in ohmic contact with some of switch electrodes 236. If membrane 212 is further deformed, membrane electrode 234 may come into physical contact with (and may make electrical (ohmic) contact with) more switch electrodes 236. In some embodiments, the amount of deformation of membrane 212 (and/or membrane electrode 234) is positively correlated with a number of the plurality of switch electrodes 236 with which membrane electrode 234 makes electrical (ohmic) contact. For example, where membrane 212 deforms under the influence of pressure, the amount of pressure may be positively correlated with the amount of deformation of membrane 212 (and/or membrane electrode 234) which is in turn positively correlated with a number of the plurality of switch electrodes 236 with which membrane electrode 234 makes electrical (ohmic) contact.

The electrical contact (or lack of electrical contact) between membrane electrode 234 and switch electrode(s) 236 may provide a switching functionality. In particular, where electrical contact is made between membrane electrode 234 and a particular one of switch electrodes 236, a corresponding circuit 240 may be completed (i.e. an electrical switch may be closed) to permit current flow between membrane electrode 234 and the particular one of switch electrodes 236. In contrast, where there is no electrical contact between membrane electrode 234 and the particular one of switch electrodes 236, current is prevented from flowing therebetween and the circuit is open (i.e. the electrical switch is opened).

In the particular case of the FIG. 3 embodiment, device 210 comprises a touch-mode electrode 246 on a side of cavity 216 generally opposed to membrane electrode 234. In the illustrated embodiment, touch-mode electrode 246 is coated with a touch-mode dielectric layer 248 which permits physical contact (between membrane electrode 234 and touch-mode dielectric layer 248) while preventing electrical contact between membrane electrode 234 and touch-mode electrode 246. Touch-mode dielectric layer 248 permits a “touch-mode” operation. Similar to device 10, a total capacitance Cₛ(p) of device 210 may be given by equation (1) as shown above. In some embodiments, C_{touch}(p) can be modelled by a circular integral as:

$${C}_{touch} ( p ) = {\int }_{0}^{\frac{3 π}{2}} {\int }_{0}^{{r}_{t} ( p )} \frac{{ε}_{d}}{{t}_{d}} rdrd θ$$

### Where:

r is the polar radial position on the membrane (e.g. membrane 12, 212) solved from 0 to rₜ(p), which is the radial edge of the contact area on the membrane;
θ is the polar angular position on the membrane solved from 0 to 3π/2 radians, which represents ¾ of the circular membrane (2π);
ϵ_{d} is the dielectric constant of the dielectric layer (e.g. dielectric layer 48, 248); and
t_{d} is the thickness of the dielectric layer.
   The switch-mode capacitance can be expressed as:

$${C}_{switch} ( p ) = {\sum }_{0}^{n ( p )} \frac{{ε}_{d} {A}_{switch}}{{t}_{d}}$$

where:
A_{switch} is the area of each of the capacitive elements in the corresponding circuit (e.g. circuit 40, 240); and,
n(p) is the total number of switch electrodes (e.g. switch electrodes 36, 236) in contact with the membrane (e.g. membrane 12, 212).
   n(p) can be calculated as a ceiling function as according to:

$$n ( p ) = ⌈ \frac{{r}_{t} ( p ) - x}{{w}_{s} + {s}_{s}} ⌉$$

where:
x is the distance from the center of the membrane to the start of the first switch electrode;
wₛ is the switch electrode width; and
sₛ is the space between switch electrodes.
   A sum of wₛ and sₛ represents the switching pitch.

It will be appreciated that for the functionality of the switch-mode capacitive pressure sensor 210 described above, it is desirable that there not be any contaminants (dielectric or conductive) in cavity 216, as such contaminants cold adversely impact the electrical characteristics (e.g. capacitance) of device 210 or the physical characteristics (e.g. deformation of membrane 212 and/or space in cavity 216 for membrane 212 to deform) of device 210. In particular, there is a desire to coat device 210 with coating layer 230 and/or to seal cavity 216, while preventing the sealing material (e.g. of coating layer 230) from reaching cavity 216. Such functionality may be achieved by providing channels 222 with Tesla valves 224. Such functionality may be achieved by applying coating layer 230 using a conformal coating technique (e.g. conformal vapor deposition) where the material of coating layer solidifies on the channel-defining surface(s) of the channel-defining wall(s), is caused to solidify on the channel-defining surface(s) or otherwise bonds or sticks to the channel-defining surface(s) of channels 222 to seal cavity 216.

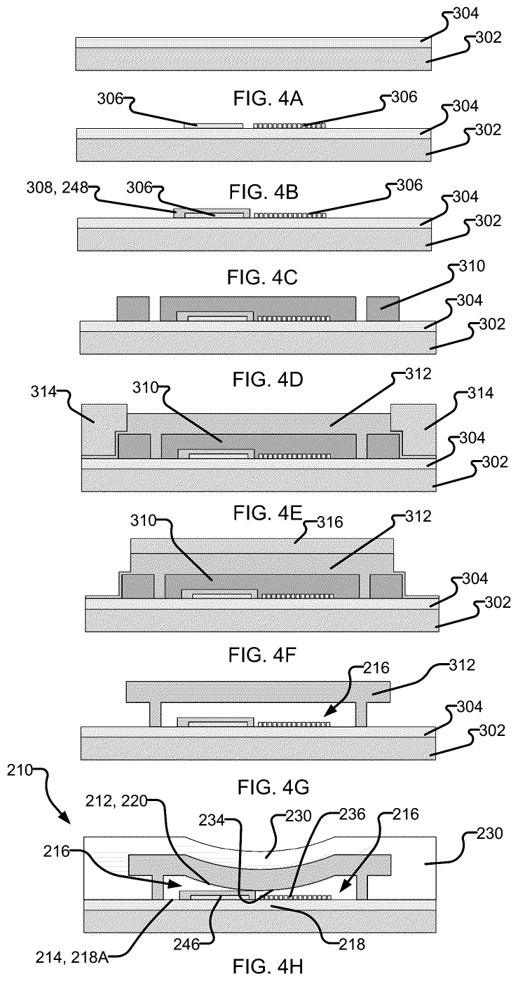

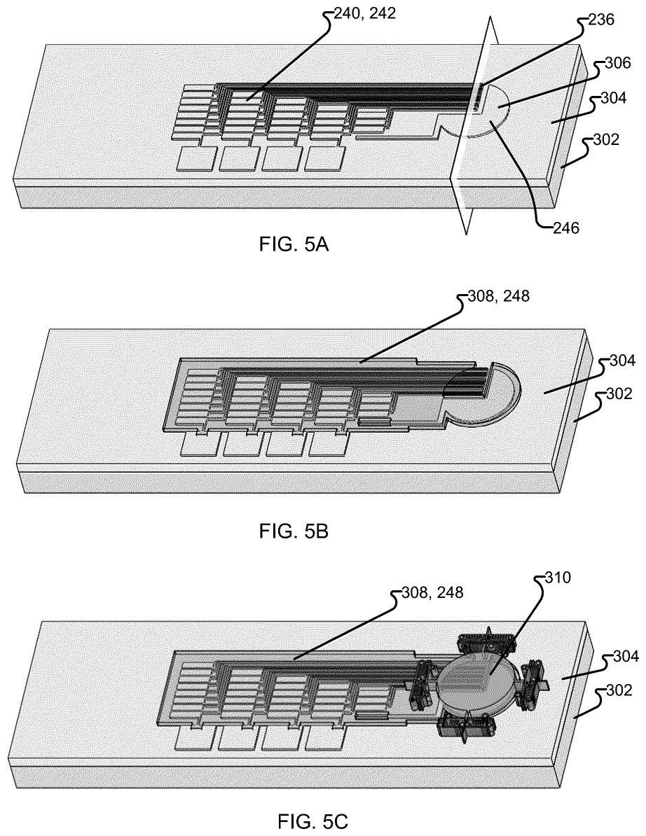

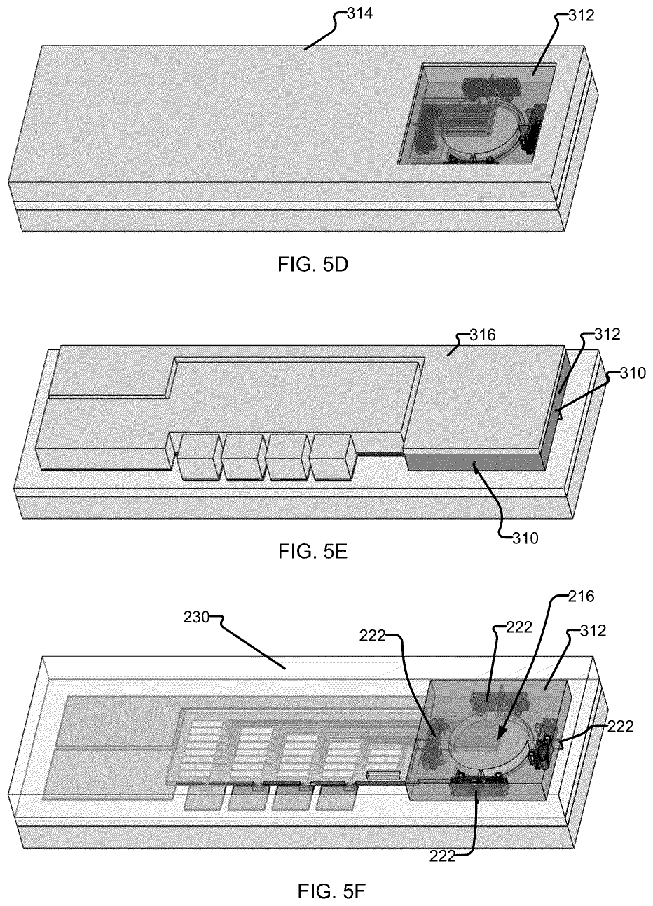

FIGS. 4A-4H (collectively, FIG. 4) schematically depict cross-sectional views of various stages in the microfabrication of device 210 and FIGS. 5A-5F schematically depict various three-dimensional views of various stages in the microfabrication of device 210 according to a particular embodiment. The microfabrication of device 210 depicted in FIG. 4 and FIG. 5 generally follows a process flow similar to the process flow described above for device 10 as shown in FIG. 2.

Device 210 may be fabricated on a silicon wafer 302 with an oxide (SiO₂) layer 304 as shown in FIG. 4A using a number of patterning steps involving UV lithography. Next, fixed electrode layer 306 is deposited on oxide layer 304 as shown in FIGS. 4B and 5A. In one particular embodiment, fixed electrode layer 306 is deposited using Ti/Au e-beam evaporation (10/100 nm) and patterned at 4-μm resolution with a bilayer lift-off process using LOR3A (425 nm baked at 200° C. for 5 min) and S1813 (1.6 μm soft baked at 115° C. for 1 min) photoresists. Fixed electrode layer 306 may provide optional touch-mode electrode 246 and switch electrodes 236 (shown in FIGS. 4B and 5A) described elsewhere herein. Bilayer lift-off may involve undercutting the LOR3A photoresist as it isotopically dissolves during the S1813 development. Next, a dielectric layer 308 is deposited and patterned as shown in FIGS. 4C and 5B to provide touch-mode dielectric layer 248 described elsewhere herein. In one particular embodiment, applying dielectric layer 308 comprises depositing a Si₃N₄ film using plasma-enhanced chemical vapor deposition and patterning dielectric layer 308 using an S1813 photoresist and a CF₄/O₂ reactive ion etching timed to minimize etching of the thermal oxide layer 304.

In FIGS. 4D and 5C, a sacrificial layer 310 is deposited. In some embodiments, sacrificial layer 310 may be deposited by spin coating, although any suitable technique may be used for the application of sacrificial layer 310. In some embodiments, sacrificial layer 310 is deposited by spin-coating a bilayer of LOR30C (e.g. 2.8 μm baked at 170° C.) and S1805 (e.g. 400 nm baked at 115° C.) photoresists. The bilayer may be UV exposed (e.g. to provide the patterning for what will become cavity 216 and channels 222 as shown best in FIG. 5C) and developed upside down to increase the likelihood that LOR30C undercut has a positive sidewall profile underneath the S1805, which assists with the sputtering step described below. Sacrificial layer 310 may be finalized with an acetone dip (e.g. 20 sec) which dissolves the S1805 while leaving the LOR30C as sacrificial layer 410.

In FIGS. 4E and 5D, membrane layer 312 is formed atop sacrificial layer 310. In some embodiments, membrane layer 312 may be deposited by first sputtering Ti/Au to provide a conformal coating that seals the previous layers and protects sacrificial layer 310 from a subsequent development process. This sputtered layer may serve as a seed layer for a subsequent electroplating step (e.g. Au electroplating) to complete membrane layer 312. The electroplating step may comprise forming an electroplating mold 314 using a UV-patterned photoresist (e.g. AZ P4620, which may be spin coated to 10 μm and soft baked at 110° C. for 1 min and then subsequently (e.g. after dicing the wafer 402 into individual chips) hard baked by ramping temperatures up and down (e.g. steps of 65° C. for 2 min, 110° C. for 1 min and 120° C. for 1 min) and then electroplating in a suitable electroplating bath (e.g. potassium aurocyanide (e.g. with a current density of 26.9 mA·mm² for ˜20 min)) to obtain a desired membrane thickness. Preferably, the time spent in the electroplating bath is sufficiently short to avoid the deterioration of electroplating mold 314. Electroplating mold 314 is then removed with suitable photoresist remover (e.g. 1165 remover at 60° C.).

In FIGS. 4F and 5E, membrane layer 312 is patterned to form the final structure of membrane 312 of device 210 and to provide access to sacrificial layer 310 and the patterned features which will become channels 222 and cavity 216. This FIG. 4F/5E step may comprise applying another layer 316 of suitable photoresist (e.g. AZ P4620 at 6 μm with a soft bake at 110° C. for 2 min and a hard bake with up and down ramps in steps of 75° C. for 1 min and 110° C. for 1 min) which may be used as protection for an etch of the metal in membrane layer 312. In one particular embodiment, this etching step may comprise an etch of gold using potassium iodide and a Ti etch using hydrofluoric acid (e.g. a 2.5 min etch of Au with potassium iodide followed by a 15 sec Ti etch with 5% hydrofluoric acid).

Then, in FIG. 4G, photoresist layer 316 is stripped using a suitable photoresist remover (e.g. a mixture of acetone and 1165 remover in equal parts). The same mixture or some other suitable solvent may be used to dissolve sacrificial layer 310 through channels 222. Channels 222 are shown in FIG. 5F after sacrificial layer 310 has been removed. Device 210 can then be suitably connected (e.g. wire bonded) to printed circuit boards and/or chip carriers or the like (not shown).

In FIGS. 4H and 5F, device 210 is coated with a sealing material (e.g. a dielectric sealing material or other suitable coating material) which provides coating layer 230. Coating layer 230 may comprise a conformal coating which be applied by any suitable technique, such as, by way of non-limiting example, vapor deposition (e.g. conformal chemical or plasma-enhanced vapor deposition) and/or the like. In some embodiments, the sealing material of coating 230 solidifies on the channel- defining surface(s) of the channel-defining wall(s), is caused to solidify on the channel-defining surface(s) or otherwise bonds or sticks to the channel-defining surface(s) of channels 22, thereby sealing channels 22 and effectively sealing cavity 216. In some embodiments, the coating layer 230 may comprise a suitable dielectric polymer, such as Parylene C, for example, as well as other types of Parylene (N, D, HT, etc.). Advantageously, Parylene C is biocompatible. Other sealing materials that could be applied to provide coating layer 230 include, without limitation, any material that can be deposited by conformal vapor deposition, such as silicon compounds (e.g. polycrystalline silicon, silicon oxides such as SiO₂ and/or the like, silicon nitride, etc.), phosphosilicate glass (PSG), tungsten, diamond, carbon, fluorocarbons organofluorines, nitrides and/or the like). Coating layer 230 provides device 210 with protection (e.g. against physical contact and/or moisture) and/or electrical insulation. In some embodiments, coating layer 230 may be applied in a vacuum environment to provide cavity 216 with a vacuum seal. During deposition, the sealing material of coating layer 230 may travel into channels 222 and is prevented from reaching cavity 216 by Tesla valves 224. The sealing material of coating layer 230 is trapped in channels 222 by Tesla valves 224 and deposited onto the channel-defining surface(s) of the wall(s) that define channels 222 where it solidifies or is caused to solidify, until channels 222 and cavity 216 are sealed. Advantageously, Tesla valves 224 in channels 222 prevent the sealing material of coating layer 230 from reaching cavity 216, so that the sealing material does not impact the performance of device 210.

In some embodiments, one or more devices 210 may be wire-bonded to PCBs to form a pressure sensor. The performance of such a pressure sensor was experimentally assessed.

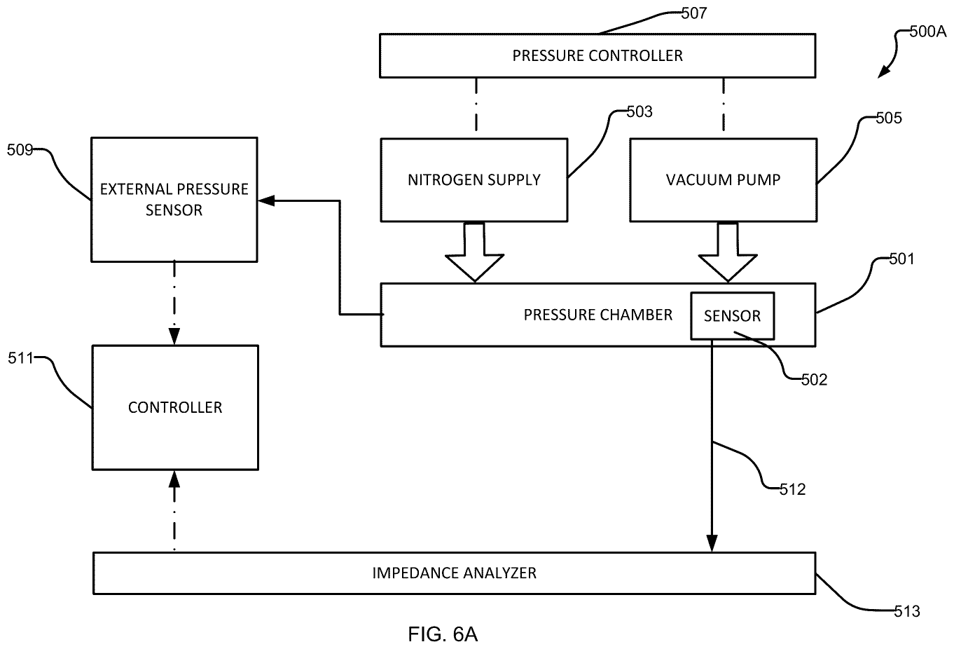

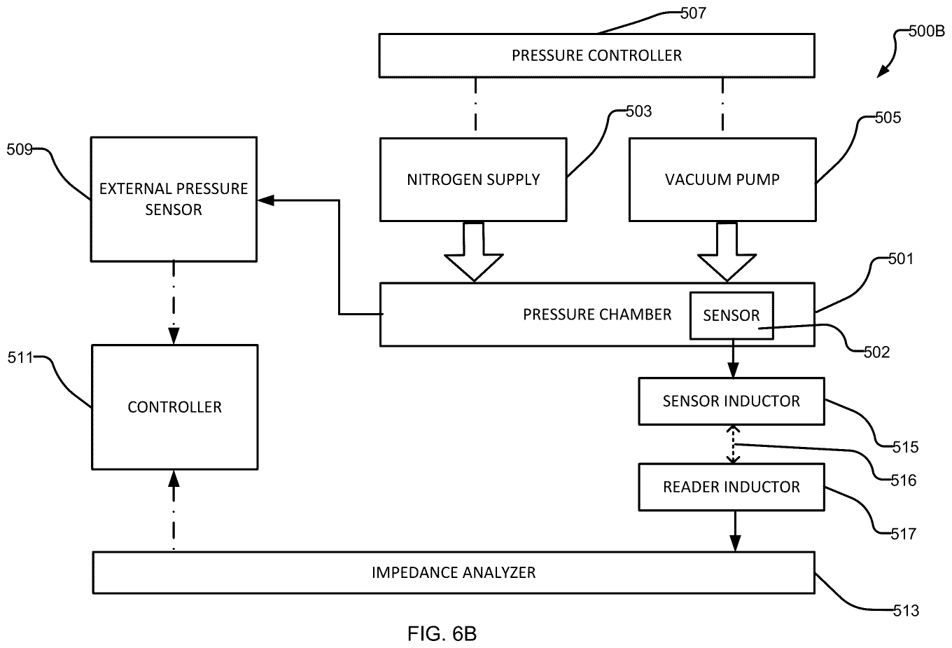

FIG. 6A is a schematic diagram of wired experimental setup 500A used to assess the performance of a capacitance-based pressure sensor 502 (e.g. pressure sensor incorporating one or more device(s) 210) according to an example embodiment. FIG. 6B is a schematic diagram of a wireless experimental setup 500B used to assess the performance of pressure sensor 502 according to another example embodiment.

Experimental setup 500A (FIG. 6A) comprises a pressure chamber 501. Pressure chamber 501 is connected to and in fluid communication with a nitrogen supply 503 and a vacuum pump 505 for varying the pressure within pressure chamber 501. Nitrogen supply 503 and vacuum pump 505 are controlled by a pressure controller 507. Pressure controller 507 may comprise any suitable pressure controller(s). In one non-limiting example, pressure controller 507 comprises OB1-MK3+ pressure controller from ElveFlow™. Pressure sensor 502 is contained within pressure chamber 501. Signals of sensor 502 are measured in response to varying pressures within pressure chamber 501. Pressure within pressure chamber 501 is measured by an external pressure sensor 509. The measured pressure data are provided to a controller 511.

In FIG. 6A, the PCB of sensor 502 is connected via a wired connection 312 through a feedthrough connector (not shown) of pressure chamber 501 to an impedance analyzer 513 for measuring an impedance of sensor 502. The experimental testing frequency was selected to be sufficiently low compared to sensor 502's self-resonant frequency to avoid interference in evaluating the impedance and capacitance of sensor 502. Prior to testing, membrane(s) 212 of device(s) 210 were conditioned by cycling gauge pressure between zero and full-scale pressure. The response measurement of each sensor was repeated three times, each by ramping the gauge pressure up and down at a rate of 10 mmHg/min while recording the capacitance data every 2.5 seconds (filtered with a 10-Hz bandwidth and 5× averaged).

Referring to FIG. 6B, experimental setup 500B is similar to experimental setup 500A except that experimental setup 500B implements a wireless connection between sensor 502 and impedance analyzer 513 instead of a wired connection. Experimental setup 500B comprises a sensor inductor 515 (e.g. transmitter coil/antenna) connected to sensor 502. Sensor inductor 515 is in an inductive coupling 516 with a reader inductor 517 (e.g. a reader coil/antenna). Reader inductor 517 is connected to impedance analyzer 513. Inductors 515, 517 enable remote tracking of pressure change applied to sensor 502.

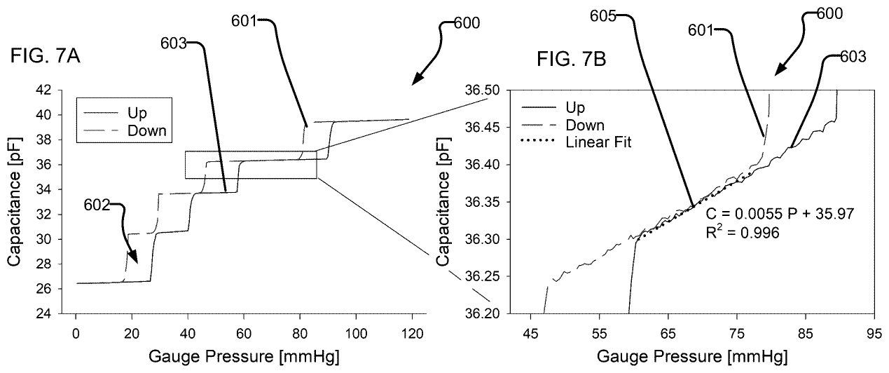

FIG. 7A shows a plot 600 of the capacitance of sensor 502 as a function of pressure according to an example embodiment. FIG. 7B shows an enlarged view of one segment of plot 600 with a linear fit according to an example embodiment.

Plot 600 shows stepwise capacitive changes of sensor 502 as a function of pressure in both line 601 corresponding to a down cycle and line 603 corresponding to an upcycle. For example, both down cycle line 601 and upcycle line 603 show features of a jump 602 in capacitance value around a pressure of about 20 mmHg. The stepwise capacitive changes are expected due to the switch mode operation of device 210 of sensor 502. Line 605 in FIG. 7B is a linear fit of portion of down cycle 601 and upcycle 603 that are between switch events (e.g. a switch electrode transitions from an untouched (open circuit) state to a touched (closed circuit) state, or vice versa). As expected, the capacitance values between down cycle 601 and upcycle 603 are similar in between switch events and exhibit a gradual increase in capacitance with pressure as expected due to the touch mode operation of device 210 of sensor 502. In a non-limiting embodiment, for a gauge pressure range of 0-120 mmHg, sensor 502 exhibits an increase of 13.21 pF with each switch event. In some embodiments, each switch event corresponds to a range of about 2.53-3.96 pF for every 12-38 mmHg in addition to the touch mode linear capacitive increase between switch events. In some embodiments, sensor 502 has a sensitivity of about 80-240 pF/mmHg. In some embodiments, for example under the wireless setup of 500B, sensor 502 has a resonant tank sensitivity of about 32.5-101.6 kHz/mmHg with frequency jumps corresponding to switch events.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Embodiments of the invention may be implemented using specifically designed hardware, configurable hardware, programmable data processors configured by the provision of software (which may optionally comprise “firmware”) capable of executing on the data processors, special purpose computers or data processors that are specifically programmed, configured, or constructed to perform one or more steps in a method as explained in detail herein and/or combinations of two or more of these. Examples of specifically designed hardware are: logic circuits, application-specific integrated circuits (“ASICs”), large scale integrated circuits (“LSIs”), very large scale integrated circuits (“VLSIs”), and the like. Examples of configurable hardware are: one or more programmable logic devices such as programmable array logic (“PALs”), programmable logic arrays (“PLAs”), and field programmable gate arrays (“FPGAs”)). Examples of programmable data processors are: microprocessors, digital signal processors (“DSPs”), embedded processors, graphics processors, math co-processors, general purpose computers, server computers, cloud computers, mainframe computers, computer workstations, and the like. For example, one or more data processors in a control circuit for a device may implement methods as described herein by executing software instructions in a program memory accessible to the processors.

Processing may be centralized or distributed. Where processing is distributed, information including software and/or data may be kept centrally or distributed. Such information may be exchanged between different functional units by way of a communications network, such as a Local Area Network (LAN), Wide Area Network (WAN), or the Internet, wired or wireless data links, electromagnetic signals, or other data communication channel.

For example, while processes or blocks are presented in a given order, alternative examples may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times.

In addition, while elements are at times shown as being performed sequentially, they may instead be performed simultaneously or in different sequences. It is therefore intended that the following claims are interpreted to include all such variations as are within their intended scope.

Software and other modules may reside on servers, workstations, personal computers, tablet computers, image data encoders, image data decoders, PDAs, color-grading tools, video projectors, audio-visual receivers, displays (such as televisions), digital cinema projectors, media players, and other devices suitable for the purposes described herein. Those skilled in the relevant art will appreciate that aspects of the system can be practised with other communications, data processing, or computer system configurations, including: Internet appliances, hand-held devices (including personal digital assistants (PDAs)), wearable computers, all manner of cellular or mobile phones, multi-processor systems, microprocessor-based or programmable consumer electronics (e.g., video projectors, audio-visual receivers, displays, such as televisions, and the like), set-top boxes, color-grading tools, network PCs, mini-computers, mainframe computers, and the like.

The invention may also be provided in the form of a program product. The program product may comprise any non-transitory medium which carries a set of computer-readable instructions which, when executed by a data processor, cause the data processor to execute a method of the invention. Program products according to the invention may be in any of a wide variety of forms. The program product may comprise, for example, non-transitory media such as magnetic data storage media including floppy diskettes, hard disk drives, optical data storage media including CD ROMs, DVDs, electronic data storage media including ROMs, flash RAM, EPROMs, hardwired or preprogrammed chips (e.g., EEPROM semiconductor chips), nanotechnology memory, or the like. The computer-readable signals on the program product may optionally be compressed or encrypted.

In some embodiments, the invention may be implemented in software. For greater clarity, “software” includes any instructions executed on a processor, and may include (but is not limited to) firmware, resident software, microcode, and the like. Both processing hardware and software may be centralized or distributed (or a combination thereof), in whole or in part, as known to those skilled in the art. For example, software and other modules may be accessible via local memory, via a network, via a browser or other application in a distributed computing context, or via other means suitable for the purposes described above.

Where a component (e.g. a software module, processor, assembly, device, circuit, etc.) is referred to above, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

Where a record, field, entry, and/or other element of a database is referred to above, unless otherwise indicated, such reference should be interpreted as including a plurality of records, fields, entries, and/or other elements, as appropriate. Such reference should also be interpreted as including a portion of one or more records, fields, entries, and/or other elements, as appropriate. For example, a plurality of “physical” records in a database (i.e. records encoded in the database's structure) may be regarded as one “logical” record for the purpose of the description above and the claims below, even if the plurality of physical records includes information which is excluded from the logical record.

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

Various features are described herein as being present in “some embodiments”. Such features are not mandatory and may not be present in all embodiments. Embodiments of the invention may include zero, any one or any combination of two or more of such features. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible).

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

What is claimed is:

1. A method for fabricating a micro-fabricated device comprising a cavity-defining surface which defines a cavity, the method comprising:
fabricating a channel that provides fluid communication with the cavity, the channel comprising a Tesla valve for permitting fluid flow in a first direction out of the cavity and through the channel while impeding fluid flow through the channel into the cavity in a second direction opposed to the first direction;
applying a sealing material to the device to thereby seal the channel, wherein applying the sealing material comprises: introducing the sealing material to the channel; and depositing the sealing material onto one or more channel-defining surfaces;
wherein the sealing material is prevented from reaching the cavity at least in part by the action of the Tesla valve.

2. The method of claim 1 wherein applying the sealing material to the device is performed in a vacuum environment to thereby vacuum seal the cavity by sealing the channel.

3. The method of claim 1 wherein applying the sealing material comprises applying the sealing material using a conformal coating process.

4. The method of claim 1 wherein applying the sealing material comprises applying the sealing material using a vapor deposition process.

5. The method of claim 1 wherein applying the sealing material comprises applying the sealing material using a conformal vapor deposition process.

6. The method of claim 1 wherein fabricating the channel comprises shaping the channel to provide one or more dead-end paths.

7. The method of claim 1 comprising fabricating the cavity, wherein fabricating the cavity comprises:
depositing a sacrificial layer on a substrate;
depositing a covering layer over the sacrificial layer;
after depositing the covering layer:
etching the sacrificial layer; and
extracting the etched sacrificial layer through the channel in the first direction to leave the cavity in the volume occupied by the sacrificial layer prior to etching.

8. The method of claim 1 wherein the cavity-defining surface comprises a plurality of electrically conductive surface elements.

9. The method of claim 8 wherein the plurality of electrically conductive surface elements comprises a membrane electrode provided by a membrane element, the membrane electrode deformable into the cavity.

10. The method of claim 9 wherein the membrane electrode is deformable under an influence of at least one of: external pressure and heat; and wherein an amount of deformation of the membrane electrode is positively correlated with an amount of the external pressure and/or heat.

11. The method of claim 9 wherein the plurality of electrically conductive surface elements comprises one or more static switch electrodes provided by one or more corresponding switch elements, the one or more static switch electrodes located on a portion of the cavity-defining surface generally opposed to the membrane electrode, and wherein the membrane electrode is deformable across the cavity to make electrical contact between the membrane electrode and the one or more switch electrodes.

12. The method of claim 11 wherein the one or more static switch electrodes comprise a plurality of static switch electrodes and wherein the method comprises locating the plurality of static switch electrodes in such a manner that an amount of deformation of the membrane electrode is positively correlated with a number of the plurality of switch electrodes with which the membrane electrode makes electrical contact.

13. The method of claim 11 wherein electrical contact between the membrane and a particular one of the of the one or more switch electrodes completes a corresponding particular circuit, the corresponding particular circuit comprising a corresponding particular circuit element.

14. The method of claim 12 wherein electrical contact between the membrane and a particular one of the plurality of switch electrodes completes a corresponding particular circuit, the corresponding particular circuit comprising a corresponding particular circuit element.

15. The method of claim 14 wherein the particular circuits completed by the electrical contact between the membrane and the particular ones of the plurality of switch electrodes are connected in parallel with one another.

16. The method of claim 13 wherein the particular circuit element comprises at least one of: one or more capacitive elements, one or more inductive elements, one or more resistive elements, one or more solid state transistors, one or more solid state diodes, one or more resonating circuit elements, one or more power sources and one or more electrically activated switches.

17. The method of claim 9 comprising fabricating a static touch-mode electrode on a side of the cavity generally opposite the membrane electrode and wherein a touch-mode capacitance provided by the membrane electrode and the touch-mode electrode is positively correlated with the amount of deformation of the membrane electrode.

18. The method of claim 17 wherein the plurality of electrically conductive surface elements comprises one or more static switch electrodes provided by one or more corresponding switch elements, the one or more static switch electrodes located on a portion of the cavity-defining surface generally opposed to the membrane electrode, and wherein the membrane electrode is deformable across the cavity under an influence of sufficient external pressure to make electrical contact between the membrane electrode and the one or more switch electrodes,
wherein the one or more static switch electrodes comprise a plurality of static switch electrodes and wherein the method comprises locating the plurality of static switch electrodes in such a manner that the amount of deformation of the membrane electrode is positively correlated with a number of the plurality of switch electrodes with which the membrane electrode makes electrical contact,
wherein electrical contact between the membrane and a particular one of the plurality of switch electrodes completes a corresponding particular circuit, the corresponding particular circuit comprising a discrete capacitive element connected in parallel with the touch-mode capacitance provided by the membrane electrode and the touch-mode electrode.

19. Use of a Tesla valve in fabricating a micro-fabricated device comprising a cavity-defining surface which defines a cavity, the use comprising:
fabricating a channel that provides fluid communication with the cavity, the channel comprising a Tesla valve for permitting fluid flow in a first direction out of the cavity and through the channel while impeding fluid flow through the channel into the cavity in a second direction opposed to the first direction;
fabricating the cavity, wherein fabricating the cavity comprises:
depositing a sacrificial layer on a substrate;
depositing a covering layer over the sacrificial layer;
after depositing the covering layer:
etching the sacrificial layer; and
extracting the etched sacrificial layer through the channel in the first direction to leave the cavity in the volume occupied by the sacrificial layer prior to etching;
after extracting the etched sacrificial layer through the channel, applying a sealing material to the device to thereby seal the channel, wherein applying the sealing material comprises: introducing the sealing material to the channel; and depositing the sealing material onto one or more channel-defining surfaces;
wherein the sealing material is prevented from reaching the cavity at least in part by the action of the Tesla valve.

20. A microelectromechanical (MEMS) device comprising:
a cavity-defining surface which defines a cavity, the cavity-defining surface comprising a plurality of electrically conductive surface elements;
a channel that provides fluid communication with the cavity, the channel comprising a Tesla valve for permitting fluid flow in a first direction out of the cavity and through the channel while impeding fluid flow through the channel into the cavity in a second direction opposed to the first direction;
wherein the channel is sealed during fabrication of the device to prevent ingress into the cavity and egress from the cavity.
